(19) United States
(12) Patent Application Publication
(10) Pub. No.: US 2026/0144051 A1
(43) Pub. Date: May 21, 2026

(54) INTERCONNECT STRUCTURE AND METHOD OF MANUFACTURING THE SAME AND INTEGRATED CIRCUIT DEVICE

(71) Applicant: SAMSUNG ELECTRONICS CO., LTD., Suwon-si (KR)

(72) Inventors: Keun Wook SHIN, Suwon-si (KR); Eun-Hyoung CHO, Suwon-si (KR); Young Min Lee, Suwon-si (KR)

(21) Appl. No.: 19/317,879

(22) Filed: Sep. 3, 2025

(30) Foreign Application Priority Data
Nov. 18, 2024 (KR) 10-2024-016453

(51) Int. Cl. H01L 23/532; H01L 21/768; H01L 23/522; H01L 23/528; H10B 12/00

(52) U.S. Cl. CPC H10W 20/4462; H10W 20/034; H10W 20/047; H10W 20/057; H10W 20/42; H10W 20/435; H10B 12/315

(57) ABSTRACT

A method of manufacturing an interconnect structure, includes: forming a first dielectric layer having a first trench, embedding a first conductive layer in the first trench, forming a second dielectric layer on the first dielectric layer and the first conductive layer, forming a second trench in the second dielectric layer to expose an upper surface of the first conductive layer, forming a carbon layer including a two-dimensional carbon material on the second dielectric layer and the first conductive layer exposed through the second trench, and exposing a sidewall of the second dielectric layer in the second trench, forming a first auxiliary layer on the sidewall of the second dielectric layer in the second trench using the carbon layer as a mask, removing the carbon layer and exposing the first conductive layer, and embedding a second conductive layer in the second trench to contact the first conductive layer.

### CROSS-REFERENCE TO RELATED APPLICATION

This application claims priority to Korean Patent Application No. 10-2024-0164537, filed on Nov. 18, 2024, and all the benefits accruing therefrom under 35 U.S.C. § 119, the content of which in its entirety is herein incorporated by reference.

### BACKGROUND

### 1. Field

An interconnect structure, a method of manufacturing the same, and an integrated circuit device are disclosed.

### 2. Description of the Related Art

In order to provide highly integrated and high-performance integrated circuit devices, it is required to reduce dimensions of unit devices constituting the integrated circuit devices, and accordingly, methods for reducing the dimensions of interconnect structures that electrically connect the unit devices are being studied.

### SUMMARY

However, as the dimension of the interconnect structure is reduced, the resistance of the wire increases, which may result in deterioration of electrical characteristics.

An embodiment provides an interconnect structure capable of reducing the dimension of the interconnect structure while preventing deterioration of electrical characteristics.

Another embodiment provides a method of manufacturing the interconnect structure.

Another embodiment provides an integrated circuit device including the interconnect structure.

According to an embodiment, a method of manufacturing an interconnect structure includes forming a first dielectric layer defining therein a first trench, embedding a first conductive layer in the first trench, forming a second dielectric layer on the first dielectric layer and the first conductive layer, forming a second trench in the second dielectric layer to expose at least a portion of an upper surface of the first conductive layer, forming a carbon layer including a two-dimensional carbon material on the second dielectric layer and the at least a portion of the upper surface of the first conductive layer exposed through the second trench to expose a sidewall of the second dielectric layer in the second trench, forming a first auxiliary layer on the sidewall of the second dielectric layer in the second trench using the carbon layer as a mask, removing the carbon layer to expose the first conductive layer, and embedding a second conductive layer in the second trench to contact the first conductive layer.

The two-dimensional carbon material may include intrinsic graphene, nanocrystalline graphene with a plurality of crystal grains, or a combination thereof.

The forming of the carbon layer may include supplying the two-dimensional carbon material in a direction parallel to the sidewall of the second dielectric layer in the second trench to deposit the carbon layer on the second dielectric layer and the at least a portion of the upper surface of the first conductive layer exposed through and the second trench.

The forming of the carbon layer may include depositing the two-dimensional carbon material by a chemical vapor deposition or an atomic layer deposition.

The method may further include forming a second auxiliary layer on a sidewall of the first dielectric layer in the first trench, prior to the embedding of the first conductive layer in the first trench.

The forming of the first auxiliary layer and the forming of the second auxiliary layer may further include depositing a metal, a semi-metal, a metal oxide, a semi-metal oxide, a metal nitride, a semi-metal nitride, a metal carbide, a semi-metal carbide, or a combination thereof by an atomic layer deposition.

The method may further include surface-treating the carbon layer after the forming of the carbon layer, wherein the surface-treating of the carbon layer may include supplying a halogen atom, a nitrogen atom, an oxygen atom, a phosphorus atom, or a combination thereof to the carbon layer.

The method may further include forming a third conductive layer electrically connected to the second conductive layer after the forming of the second conductive layer, where the first conductive layer and the third conductive layer may each be a wire, and the second conductive layer may be a via connecting the first conductive layer and the third conductive layer.

According to another embodiment, an interconnect structure includes a first dielectric layer and a second dielectric layer, which are sequentially stacked, a first conductive layer embedded in the first dielectric layer, a second conductive layer embedded in a trench of the second dielectric layer and in contact with an upper surface of the first conductive layer, a first auxiliary layer between a side of the second conductive layer and an inner side of the second dielectric layer, and a two-dimensional carbon material in contact with the side of the second conductive layer and an bottom surface of the first auxiliary layer.

An amount of the two-dimensional carbon material may be about 0.001 atomic percentages (at %) to about 5 at % with respect to a total number of atoms within a same height as the two-dimensional carbon material in the trench of the second dielectric layer.

The interconnect structure may further include a second auxiliary layer between the first conductive layer and the first dielectric layer, and a carbon layer disposed between the first auxiliary layer and the second auxiliary layer and including the two-dimensional carbon material.

According to another embodiment, an interconnect structure includes a first dielectric layer and a second dielectric layer, which are sequentially stacked, a first conductive layer embedded in the first dielectric layer, a second conductive layer embedded in the second dielectric layer and in contact with an upper surface of the first conductive layer, a first auxiliary layer between a side of the second conductive layer and an inner side of the second dielectric layer, a second auxiliary layer between the first conductive layer and the first dielectric layer, and a carbon layer disposed between the first auxiliary layer and the second auxiliary layer and including a two-dimensional carbon material.

The two-dimensional carbon material may include intrinsic graphene, nanocrystalline graphene with a plurality of crystal grains, or a combination thereof.

The interconnect structure may further include a third conductive layer electrically connected to the second conductive layer, wherein the first conductive layer and the third conductive layer may each be a wire, and the second conductive layer may be a via connecting the first conductive layer and the third conductive layer.

The first auxiliary layer and the second auxiliary layer may each independently include a diffusion barrier layer, an adhesion auxiliary layer, or a combination thereof, and the first auxiliary layer and the second auxiliary layer may each independently include a metal, a semi-metal, a metal oxide, a semi-metal oxide, a metal nitride, a semi-metal nitride, a metal carbide, a semi-metal carbide, or a combination thereof.

According to another embodiment, an integrated circuit device including the interconnect structure is provided.

By the features above, it is possible to effectively reduce the dimension of the interconnect structure while preventing deterioration of electrical characteristics.

### BRIEF DESCRIPTION OF THE DRAWINGS

FIGS. 1 to 10 are cross-sectional views showing examples of a method of manufacturing an interconnect structure according to an embodiment,

FIG. 11 is a plan view showing an example of an integrated circuit device according to an embodiment,

FIG. 12 is a perspective view showing an example of the integrated circuit element of FIG. 11,

FIG. 13 is a schematic view showing an example of a transistor of the integrated circuit device of FIG. 11, and

FIG. 14 is a conceptual view showing an example of an electronic device according to an embodiment.

### DETAILED DESCRIPTION

Hereinafter, the embodiments will be described in detail so that those of ordinary skill in the art may easily implement them. However, the actually applied structure may be implemented in several different forms and is not limited to the embodiments described herein.

The terminology used herein is used to describe embodiments only, and is not intended to limit the present disclosure. The singular expression includes the plural expression unless the context clearly dictates otherwise.

Here, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “above” another component, the component may be directly on, under, on the left of, or on the right of the other component, or may be on, under, on the left of, or on the right of the other component in a non-contact manner. In addition, unless explicitly described to the contrary, the word “comprise,” and variations such as “comprises” or “comprising,” will be understood to imply the inclusion of stated elements.

The term “layer” includes a construction having a shape formed on a part of a region, in addition to a construction having a shape formed on an entire region.

As used herein, the term “the” or similar indicative terms correspond to both the singular form and the plural form. The steps of all methods described herein may be performed in any suitable order unless otherwise indicated herein or otherwise clearly contradicted by context.

Here, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Hereinafter, “metal” is interpreted as a concept including metals and metalloids (semi-metals).

An example of a method of manufacturing an interconnect structure according to an embodiment is described with reference to the drawings.

The interconnect structure may be a structure in which a plurality of conductive layers are electrically connected in a dielectric layer, and for example, may be a structure in which a plurality of conductive layers having a predetermined aspect ratio are embedded in a dielectric layer and stacked along the thickness direction of the substrate.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

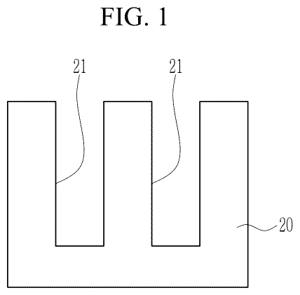

FIGS. 1 to 10 are cross-sectional views showing examples of a method of manufacturing an interconnect structure according to an embodiment.

Referring to FIG. 1, a lower dielectric layer 20 is formed on a substrate (not shown).

The substrate may be a semiconductor substrate, the semiconductor substrate may include, for example, a Group IV semiconductor material, a Group III-V semiconductor compound, or a Group II-VI semiconductor compound, for example, a Group IV semiconductor material including at least one or more of Si, Ge, Sn, or C, a Group III-V compound semiconductor material in which at least one or more of B, Ga, In, or Al are combined with at least one or more of N, P, As, or Sb, or a Group II-VI compound semiconductor material in which at least one or more of Be, Mg, Cd, or Zn are combined with at least one or more of O, S, Se, or Te. For example, the semiconductor substrate may include Si, Ge, SiC, SiGe, SiGeC, Ge alloy, GaAs, InAs, InP, and the like, but is not limited thereto.

The substrate may include at least one semiconductor device (not shown) in and/or on the substrate, for example at least one of a transistor, a capacitor, a diode, or a resistor, but is not limited thereto.

The lower dielectric layer 20 may an inter-metal dielectric (IMD). The lower dielectric layer 20 may include, for example, a low-k dielectric material, and may include, for example, a dielectric material having a dielectric constant of less than or equal to about 3.6. The lower dielectric layer 20 may include, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, semi-a metal oxynitride, a carbon-doped metal oxynitride, a carbon-doped semi-metal oxynitride, or a combination thereof. The lower dielectric layer 20 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto. The lower dielectric layer 20 may be formed, for example, by chemical vapor deposition.

Next, a lower trench 21 is formed in the lower dielectric layer 20. The lower trench 21 may be formed, for example, by a photolithography.

The lower trench 21 may be formed with a predetermined width and depth considering the dimension of the lower conductive layer 40 described later, and may have, for example, a relatively narrow width and a high aspect ratio. Here, the aspect ratio could be the ratio of depth to width. For example, the width of the lower trench 21 may be less than about 20 nanometers (nm), and within the above range may be about 1 nm to about 19 nm, about 1 nm to about 15 nm, about 1 nm to about 12 nm, about 1 nm to about 10 nm, about 1 nm to about 9 nm, about 1 nm to about 8 nm, about 1 nm to about 7 nm, about 1 nm to about 6 nm or about 1 nm to about 5 nm. For example, the aspect ratio of the lower trench 21 may be greater than or equal to about 3, and within the above range may be about 3 to about 100, about 3 to about 80, about 3 to about 70, about 3 to about 60, about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30.

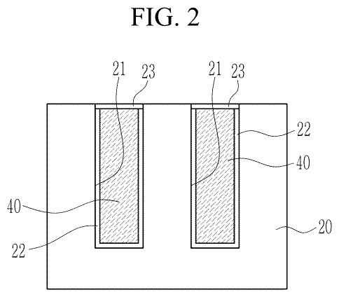

Referring to FIG. 2, a lower auxiliary layer 22 is formed in a lower trench 21 of a lower dielectric layer 20. The lower auxiliary layer 22 may be formed to a very thin thickness, for example, by atomic layer deposition (ALD), and may be formed as a continuous thin film along the sidewall of the lower dielectric layer 20 in the lower trench 21. The lower auxiliary layer 22 may have a thin thickness of, for example, less than about 5 nm, and within the above range may be less than or equal to about 4 nm, less than or equal to about 3 nm, less than or equal to about 2 nm, greater than about 1 Å and less than or equal to about 5 nm, greater than about 1 Å and less than or equal to about 4 nm, greater than about 1 Å and less than or equal to about 3 nm, or greater than about 1 Å and less than or equal to about 2 nm.

The lower auxiliary layer 22 may have one or more layers, and may include, for example, a diffusion barrier layer, an adhesion auxiliary layer, or a combination thereof. The lower auxiliary layer 22 may be disposed between the lower conductive layer 40 and the lower dielectric layer 20 to be described later, and may block direct contact between the lower conductive layer 40 and the lower dielectric layer 20, thereby preventing or reducing diffusion of metal from the lower conductive layer 40 to the lower dielectric layer 20 and increasing adhesion of the lower conductive layer 40 to the sidewall of the lower dielectric layer 20 in the lower trench 21.

The lower auxiliary layer 22 may include, for example, a metal, a semi-metal, a metal oxide, a semi-metal oxide, a metal nitride, a semi-metal nitride, a metal carbide, a semi-metal carbide, or a combination thereof, and may include, for example, but not limited to, Ti, Ta, TiN, TaN, SiN, or a combination thereof.

Next, a lower conductive layer 40 is embedded in the lower trench 21 of the lower dielectric layer 20. The lower conductive layer 40 may be deposited, for example, by chemical vapor deposition or physical vapor deposition, and additionally, the surface of the lower conductive layer 40 may be planarized to match the surface of the lower dielectric layer 20 by chemical mechanical polishing (CMP), etc.

The lower conductive layer 40 may be a wire. The lower conductive layer 40 may be a three-dimensional structure having a width, a length, and a thickness, wherein the longitudinal direction of the lower conductive layer 40 may be a direction in which electrons move and may be a direction perpendicular to the width direction and the thickness direction, respectively.

A line width of the lower conductive layer 40 may be on the nanometer level, for example, less than about 20 nm, less than or equal to about 18 nm, less than or equal to about 15 nm, less than or equal to about 13 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, greater than or equal to about 1 nm and less than 20 nm, about 1 nm to about 18 nm, about 1 nm to about 15 nm, about 1 nm to about 13 nm, about 1 nm to about 12 nm, about 1 nm to about 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3 nm.

The lower conductive layer 40 may have a high aspect ratio, wherein the aspect ratio may be the ratio of height to width. The aspect ratio of the lower conductive layer 40 may be greater than or equal to about 3, and within the above range may be about 3 to about 100, about 3 to about 80, about 3 to about 70, about 3 to about 60, about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30. The lower conductive layer 40 may be a narrow and deep wire with a high aspect ratio in the above range.

The lower conductive layer 40 may include, for example, a metal or a metal alloy, and may include Cu, Ru, Rh, Ir, Mo, W, Pd, Pt, Co, Ta, Ti, Ni, Pd, alloys thereof, or combinations thereof, but is not limited thereto.

Next, a capping layer 23 may be additionally formed on the lower conductive layer 40. The capping layer 23 may be, for example, a protective layer and/or an anti-scattering layer. The capping layer 23 may include, for example, a conductor, a semiconductor, and/or an insulator, and may include, for example, graphene, metal-doped graphene, or a combination thereof, but is not limited thereto. The capping layer 23 may be formed by chemical vapor deposition, physical vapor deposition, or atomic layer deposition, and may be omitted.

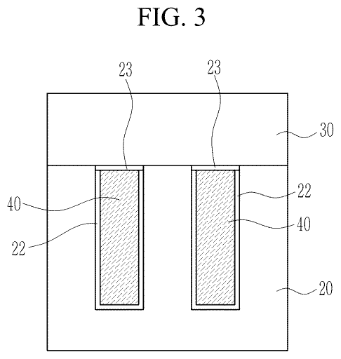

Referring to FIG. 3, an intermediate dielectric layer 30 is formed on the lower dielectric layer 20 and the lower conductive layer 40 (or capping layer 23). Accordingly, the lower dielectric layer 20 and the middle dielectric layer 30 may be sequentially stacked along the thickness direction of the substrate (not shown). The intermediate dielectric layer 30 may also be an interlayer inter-metal dielectric (IMD) film and may be formed, for example, by chemical vapor deposition.

The intermediate dielectric layer 30 may include a dielectric material that is the same as or different from the lower dielectric layer 20, and for example, may include a low-k dielectric material, for example, a dielectric material having a dielectric constant of less than or equal to about 3.6. The intermediate dielectric layer 30 may include, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped metal oxynitride, or a combination thereof. The intermediate dielectric layer 30 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto.

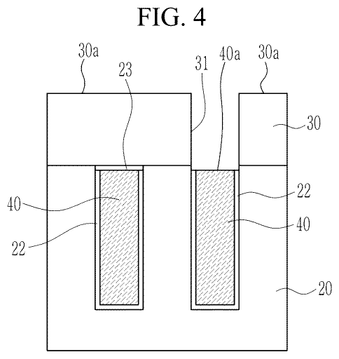

Referring to FIG. 4, an intermediate trench 31 is formed in the intermediate dielectric layer 30. The intermediate trench 31 may be formed, for example, by a photolithography method.

The intermediate trench 31 may be formed at a position corresponding to the lower conductive layer 40, and thus at least a portion of the upper surface 40a of the lower conductive layer 40 may be exposed through the intermediate trench 31. In the forming of the intermediate trench 31, the capping layer 23 formed on an upper portion of the lower conductive layer 40 may also be removed.

The intermediate trench 31 may be formed with a predetermined width and depth considering the dimensions of the intermediate conductive layer 50 described later, and may have, for example, a relatively narrow width and a high aspect ratio.

A width of the intermediate trench 31 may be equal to or wider than the width of the lower trench 21, and for example, the width of the intermediate trench 31 may be less than about 30 nm, and within the above range, may be greater than or equal to about 1 nm and less than about 30 nm, about 1 nm to about 28 nm, about 1 nm to about 25 nm, about 1 nm to about 20 nm, about 1 nm to about 19 nm, about 1 nm to about 15 nm, about 1 nm to about 12 nm, about 1 nm to about 10 nm, about 1 nm to about 9 nm, about 1 nm to about 8 nm, about 1 nm to about 7 nm, about 1 nm to about 6 nm, or about 1 nm to about 5 nm.

For example, the aspect ratio of the intermediate trench 31 may be greater than or equal to about 3, and within the above range, may be about 3 to about 100, about 3 to about 80, about 3 to about 70, about 3 to about 60, about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30.

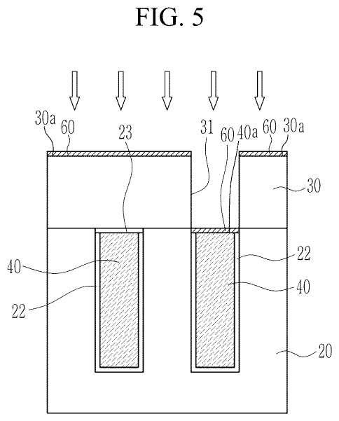

Referring to FIG. 5, a carbon layer 60 is formed on the upper surface 40a of the lower conductive layer 40 exposed through the intermediate dielectric layer 30 and the intermediate trench 31. The carbon layer 60 may serve as a mask that shields the remaining area except for the exposed area in order to form an intermediate auxiliary layer 32 described later in a predetermined area, and may be a sacrificial layer that is removed in the process described later.

The carbon layer 60 may include a two-dimensional carbon material. The two-dimensional carbon material may include, for example, graphene, such as intrinsic graphene, nanocrystalline graphene having a plurality of crystal grains, or a combination thereof. Here, the two-dimensional material may be a crystalline material with a thickness of only a few atomic layers, typically one or two, while exhibiting a large lateral dimension. The carbon layer 60 may include n monolayers made of, for example, graphene, where n may be from 1 to 10, but is not limited thereto.

The graphene may have hydrophobic surface characteristics, and thus may effectively serve as a mask due to the difference in surface characteristics with respect to the intermediate dielectric layer 30 in the formation of the intermediate auxiliary layer 32 described later. For example, the contact angle of the carbon layer 60 may be, for example, greater than or equal to about 60 degrees, and within the above range, may be about 60 degrees to about 110 degrees, about 70 degrees to about 110 degrees, about 80 degrees to about 110 degrees, or about 90 degrees to about 110 degrees.

For example, the carbon layer 60 may include nanocrystalline graphene. The nanocrystalline graphene may include a plurality of crystal grains having a size (e.g., lateral size) of several to tens of nanometers and grain boundaries existing between adjacent crystal grains. For example, an average size of the plurality of crystal grains (e.g., average lateral size) may be about 0.5 nm to 100 nm, and within that range may be about 0.5 nm to about 80 nm, about 1 nm to about 80 nm, or about 1 nm to about 60 nm.

The nanocrystalline graphene, unlike intrinsic graphene, may have less than about 100% of a ratio of carbon having a sp² bond, for example, less than or equal to about 99%, or for example, about 50% to about 99% with respect to total carbon. The nanocrystalline graphene may include hydrogen in addition to the carbon, wherein the hydrogen may be, for example, included in an amount of about 1 at % to about 20 at % with respect to the total number of atoms. The nanocrystalline graphene may have lower density than the intrinsic graphene, for example, density of less than or equal to about 2.1 grams per cubic centimeter (g/cc) or for example, about 1.6 to about 2.1 g/cc.

The nanocrystalline graphene may be deposited and/or grown at a relatively lower temperature than the intrinsic graphene, for example, at less than or equal to about 700° C., less than or equal to about 600° C., less than or equal to about 500° C., for example, about 200° C. to about 700° C., about 200° C. to about 600° C., or about 200° C. to about 500°C.

The carbon layer 60 may be deposited, for example, by chemical vapor deposition or atomic layer deposition. The chemical vapor deposition may be, for example, plasma enhanced chemical vapor deposition, and the plasma enhanced chemical vapor deposition may use, for example, a capacitively coupled plasma (CCP), an inductively coupled plasma (ICP), or a microwave plasma.

For example, the two-dimensional carbon material may be supplied vertically to the surface 30a of the intermediate dielectric layer 30 on the intermediate dielectric layer 30, and accordingly, the two-dimensional carbon material may be selectively deposited only on the upper surface of the intermediate dielectric layer 30 and the upper surface of the lower conductive layer 40 exposed through the intermediate trench 31, and may not be deposited on the sidewall of the intermediate dielectric layer 30 in the intermediate trench 31. Therefore, the carbon layer 60 may be selectively formed only on the upper surface of the intermediate dielectric layer 30 and the upper surface of the lower conductive layer 40 exposed through the intermediate trench 31, and the sidewall of the intermediate dielectric layer 30 may be exposed.

A thickness of the carbon layer 60 may be, for example, less than about 10 nm, and within the above range may be less than or equal to about 8 nm, less than or equal to about 5 nm, or less than or equal to about 3 nm, and within the above range may be greater than or equal to about 0.3 nm and less than 10 nm, about 0.3 nm to about 8 nm, about 0.3 nm to about 5 nm, about 0.3 nm to about 3 nm, greater than or equal to about 0.5 nm and less than about 10 nm, about 0.5 nm to about 8 nm, about 0.5 nm to about 5 nm, or about 0.5 nm to about 3 nm.

For example, after the forming of the carbon layer 60, the surface-treating of the carbon layer 60 may be further included. The surface-treating may include supplying a predetermined dopant capable of modifying or strengthening surface characteristics to the surface of the carbon layer 60, and the dopant may be, for example, a halogen atom (F, Cl, Br and/or I), a nitrogen atom (N), an oxygen atom (O), a phosphorus atom (P), or a combination thereof, but is not limited thereto. The dopant supplied to the carbon layer 60 may be supplied at a concentration of about 0.1 at % to about 10 at %, and within the above range may be supplied at a concentration of about 0.1 at % to about 7 at %, about 0.1 at % to about 5 at %, or about 0.1 at % to about 3 at %. The surface-treated carbon layer 60 may have a higher hydrophobic surface characteristic, so that it may more effectively perform the role of a mask due to a difference in surface characteristic with the intermediate dielectric layer 30 in the forming of the intermediate auxiliary layer 32 described later.

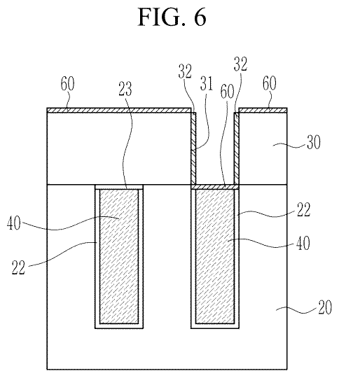

Referring to FIG. 6, an intermediate auxiliary layer 32 is formed on the sidewall of the intermediate dielectric layer 30 in the intermediate trench 31. The intermediate auxiliary layer 32 may be formed, for example, by atomic layer deposition (ALD), and since the intermediate auxiliary layer 32 may be deposited using the carbon layer 60 as a mask, it may be selectively formed only on the sidewall of the intermediate dielectric layer 30 that is not covered with the carbon layer 60, and may not be formed on the intermediate dielectric layer 30 and the lower conductive layer 40 that are covered with the carbon layer 60.

For example, the surface of the intermediate dielectric layer 30 may have a relatively low contact angle (e.g., less than about 50 degrees) and may have surface characteristics different from the aforementioned carbon layer 60 that has highly hydrophobic surface characteristics. Due to these differences in surface characteristics, the deposition material for forming the intermediate auxiliary layer 32 (e.g., a precursor of atomic layer deposition) may be selectively attached only to the surface of the exposed intermediate dielectric layer 30, that is, only to the side surface of the intermediate dielectric layer 30 in the intermediate trench 31, and thus, the intermediate auxiliary layer 32 may be selectively formed only on the side surface of the intermediate dielectric layer 30.

The intermediate auxiliary layer 32 may have a thin thickness of, for example, less than about 5 nm, and within the above range may be less than or equal to about 4 nm, less than or equal to about 3 nm, less than or equal to about 2 nm, greater than about 1 Å and less than or equal to about 5 nm, greater than about 1 Å and less than or equal to about 4 nm, greater than about 1 Å and less than or equal to about 3 nm, or greater than about 1 Å and less than or equal to about 2 nm.

The intermediate auxiliary layer 32 may have one or more layers, and may include, for example, a diffusion barrier layer, an adhesion auxiliary layer, or a combination thereof. The intermediate auxiliary layer 32 may block direct contact between the intermediate conductive layer 50 and the intermediate dielectric layer 30, which will be described later, thereby preventing or reducing diffusion of metal from the intermediate conductive layer 50 to the intermediate dielectric layer 30, and may increase adhesion of the intermediate conductive layer 50 to the sidewall of the intermediate dielectric layer 20 in the intermediate trench 31.

The intermediate auxiliary layer 32 may include, for example, a metal, a semi-metal, a metal oxide, a semi-metal oxide, a metal nitride, a semi-metal nitride, a metal carbide, a semi-metal carbide, or a combination thereof, and may include, for example, but not limited to, Ti, Ta, TiN, TaN, SiN, or a combination thereof.

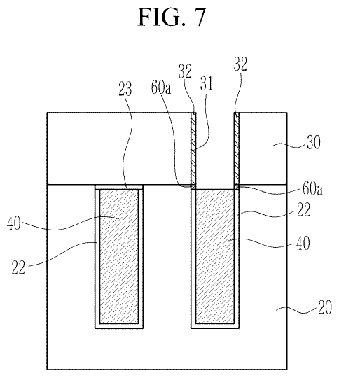

Referring to FIG. 7, the carbon layer 60 is removed. The carbon layer 60 may be removed, for example, by ashing. The two-dimensional carbon material such as graphene may be effectively removed by ashing using, for example, hydrogen plasma. As the carbon layer 60 is removed, the upper surface of the lower conductive layer 40 may be exposed through the intermediate trench 31. That is, the intermediate auxiliary layer 32 is formed only on the sidewall of the intermediate dielectric layer 30 in the intermediate trench 31, and the lower conductive layer 40 may be exposed.

For example, the two-dimensional carbon material that is not removed (e.g., a portion 60a) may remain under the bottom surface of the intermediate auxiliary layer 32. The two-dimensional carbon material remaining under the bottom surface of the intermediate auxiliary layer 32 may be less than about 5 at %, and may be within the above range about 0.001 at % to about 5 at %, about 0.001 to about 4 at %, about 0.001 at % to about 3 at %, about 0.001 at % to about 2 at %, or about 0.001 at % to about 1 at % with respect to a total number of atoms within the same height as the portion 60a in the intermediate trench 31. The remaining two-dimensional carbon material may be identified, for example, by x-ray photoelectron spectrometry (XPS) or energy dispersive spectroscopy (EDS).

For example, a portion 60a of the carbon layer 60 covered with the intermediate auxiliary layer 32 may remain without being removed. For example, the portion 60a interposed between the lower auxiliary layer 22 and the intermediate auxiliary layer 32 of the carbon layer 60 may remain without being removed.

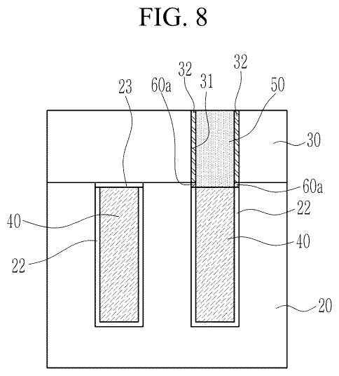

Referring to FIG. 8, an intermediate conductive layer 50 is embedded in an intermediate trench 31 of an intermediate dielectric layer 30. The intermediate conductive layer 50 may be deposited, for example, by chemical vapor deposition or physical vapor deposition, and additionally, the surface of the intermediate conductive layer 50 may be planarized to match the surface of the intermediate dielectric layer 30 by chemical mechanical polishing (CMP), etc. The intermediate conductive layer 50 may be in contact with the upper surface of the lower conductive layer 40 in the intermediate trench 31, and in this way, the intermediate conductive layer 50 and the lower conductive layer 40 are in direct contact without the intervention of a capping layer 23 or an intermediate auxiliary layer 32, thereby reducing resistance and improving electrical characteristics.

The intermediate conductive layer 50 may be a via. The intermediate conductive layer 50 may be in contact with the lower conductive layer 40 and the upper conductive layer 70 described later, respectively, and may electrically connect the lower conductive layer 40 and the upper conductive layer 70.

The intermediate conductive layer 50 may include, for example, a metal or a metal alloy, and may include Cu, Ru, Rh, Ir, Mo, W, Pd, Pt, Co, Ta, Ti, Ni, Pd, alloys thereof, or combinations thereof, but is not limited thereto.

A line width of the intermediate conductive layer 50 may be on the nanometer level, for example, less than about 20 nm, less than or equal to about 18 nm, less than or equal to about 15 nm, less than or equal to about 13 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, greater than or equal to about 1 nm and less than about 20 nm, about 1 nm to about 18 nm, about 1 nm to about 15 nm, about 1 nm to about 13 nm, about 1 nm to about 12 nm, about 1 nm to about 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3 nm.

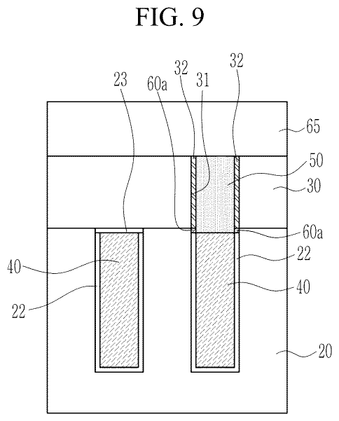

Referring to the following FIG. 9, an upper dielectric layer 65 is formed on the intermediate dielectric layer 30 and the intermediate conductive layer 50. Accordingly, the lower dielectric layer 20, the intermediate dielectric layer 30, and the upper dielectric layer 65 may be sequentially stacked along the thickness direction of the substrate (not shown). The upper dielectric layer 65 may also be an inter-metal dielectric (IMD) film and may be formed, for example, by chemical vapor deposition.

The upper dielectric layer 65 may include a dielectric material that is the same as or different from the lower dielectric layer 20 and/or the intermediate dielectric layer 30, for example, may include a low-k dielectric material, for example, a dielectric material having a dielectric constant of less than or equal to about 3.6. The upper dielectric layer 65 may include, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped metal oxynitride, or a combination thereof. The upper dielectric layer 65 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto.

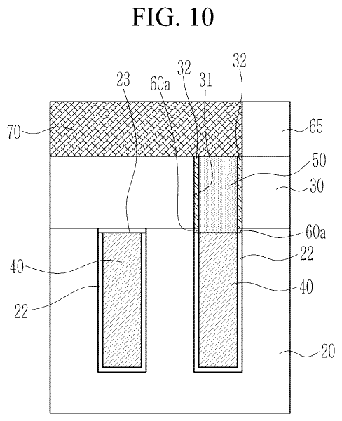

Referring to FIG. 10, an upper trench 67 is formed in an upper dielectric layer 65, and an upper conductive layer 70 is formed in the upper trench 67. The upper conductive layer 70 may be a three-dimensional structure having a width, a length, and a thickness, where the longitudinal direction of the upper conductive layer 70 may be a direction in which electrons move and may be a direction perpendicular to the width direction and the thickness direction, respectively. The upper conductive layer 70 may be a wire. The longitudinal direction of the upper conductive layer 70 may be different from the longitudinal direction of the lower conductive layer 40, and for example, the longitudinal direction of the upper conductive layer 70 may be substantially perpendicular to the longitudinal direction of the lower conductive layer 40.

The upper conductive layer 70 may be in contact with the upper surface of the intermediate conductive layer 50 and may be electrically connected to the lower conductive layer 40 through the intermediate conductive layer 50. The upper conductive layer 70 may include, for example, a metal or a metal alloy, and may include, for example, Cu, Ru, Rh, Ir, Mo, W, Pd, Pt, Co, Ta, Ti, Ni, Pd, alloys thereof, or a combination thereof, but is not limited thereto.

As described above, by forming an intermediate auxiliary layer 32 in the intermediate trench 31, diffusion of metal from the intermediate conductive layer 50 to the intermediate dielectric layer 30 may be prevented or reduced, and adhesion between the intermediate dielectric layer 30 and the intermediate conductive layer 50 may be increased. In addition, by selectively forming the intermediate auxiliary layer 32 only on the sidewall of the intermediate dielectric layer 30 using the carbon layer 60 as a mask and not forming the intermediate auxiliary layer 32 on the upper surface of the lower conductive layer 40, the lower conductive layer 40 and the intermediate conductive layer 50 may be formed to be in direct contact, thereby reducing a resistance between the lower conductive layer 40 and the intermediate conductive layer 50 and improving the electrical characteristics.

By the method described above, an interconnect structure 100 may be formed, which includes a lower dielectric layer 20 and an intermediate dielectric layer 30 stacked and a lower conductive layer 40 embedded in the lower dielectric layer 20, an intermediate conductive layer 50 embedded in the intermediate dielectric layer 30, and an upper conductive layer 70 electrically connected to the intermediate conductive layer 50.

As described above, a lower auxiliary layer 22 and an intermediate auxiliary layer 32 are formed between the lower conductive layer 40 and the lower dielectric layer 20 and between the intermediate conductive layer 50 and the intermediate dielectric layer 30, respectively, while the upper surface of the lower conductive layer 40 and the lower surface of the intermediate conductive layer 50 are in direct contact without the interposition of a separate layer, so that the electrical characteristics of the interconnect structure 100 may be improved without an increase in resistance.

The interconnect structure 100 may be included in an integrated circuit device. The integrated circuit device may include DRAM or logic device, but is not limited thereto. The integrated circuit device may include unit devices including, for example, a transistor, a capacitor, a diode, a resistor, or a combination thereof, electrically connected to the aforementioned lower conductive layer 40, intermediate conductive layer 50, and/or upper conductive layer 70. The integrated circuit device may be applied to wire (e.g., bit lines, word lines, etc.) and/or BEOL (back end of line) structures that are connected to unit devices such as transistors.

For example, the transistor may have various structures, for example FinFET, GAAFET, MBCFET, CFET or VFET, but is not limited thereto. For example, the transistor may be a C-FET (complementary field effect transistor), an MBC-FET (multi bridge channel field effect transistor), or a CNT-FET (carbon nanotube field effect transistor), but is not limited thereto.

An example of an integrated circuit device according to an embodiment is described.

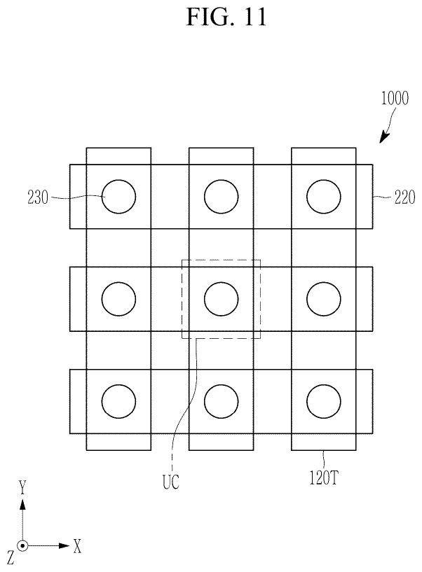

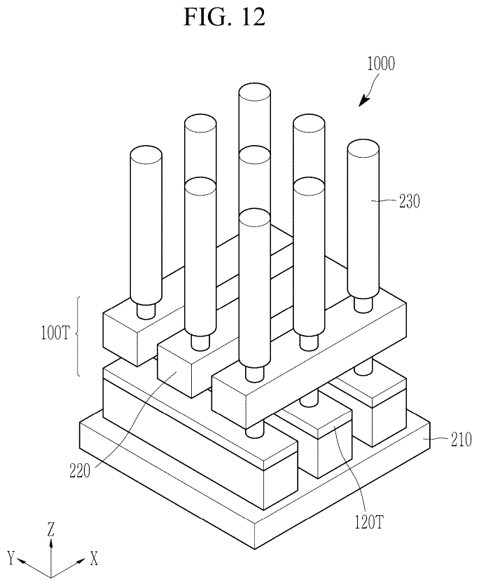

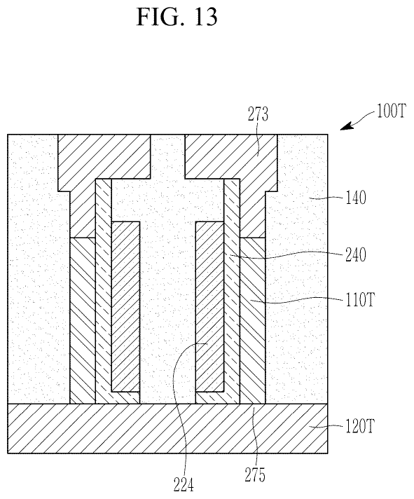

FIG. 11 is a plan view showing an example of an integrated circuit device according to an embodiment, FIG. 12 is a perspective view showing an example of the integrated circuit device of FIG. 11, and FIG. 13 is a schematic view showing an example of a transistor of the integrated circuit device of FIG. 11.

Referring to FIGS. 11 and 12, an integrated circuit device 1000 according to the present embodiment includes a plurality of active regions partitioned by a plurality of bit lines 120T and a plurality of word lines 220, and the plurality of active regions are arranged in an array form. A unit cell UC including a transistor 100T and a capacitor 230 may be disposed in each active region. The integrated circuit device 1000 according to the present embodiment may be a DRAM device.

An integrated circuit device 1000 according to the present embodiment includes a semiconductor substrate 210, a bit line 120T, a word line 220, a transistor 100T, and a capacitor 230.

The semiconductor substrate 210 may include a Group IV semiconductor material such as silicon (Si), germanium (Ge), silicon-germanium (SiGe), and silicon carbide (SiC); a Group III-V semiconductor material such as GaP, GaAs, and GaSb; or a combination thereof. For example, the semiconductor substrate 210 may be a silicon-on-insulator (SOI) substrate or a germanium-on-insulator (GOI) substrate.

The bit line 120T and the word line 220 extend in different directions on the semiconductor substrate 210. For example, the bit line 120T and the word line 220 may be arranged perpendicular to each other. The bit line 120T and the word line 220 may be disposed at different heights from the surface of the semiconductor substrate 210. For example, the bit line 120T may be disposed closer to the surface of the semiconductor substrate 210 than the word line 220.

The bit line 120T and the word line 220 are each electrically connected to a transistor 100T, which will be described later. At least one of the bit line 120T and the word line 220 may include a lower conductive layer 40 or an upper conductive layer 70, and may include an intermediate conductive layer 50 interposed between the lower conductive layer 40 and the upper conductive layer 70. At least one of the bit line 120T and the word line 220 may have a line width of less than about 20 nm. For example, each of the bit line 120T and the word line 220 may have a line width of less than about 20 nm.

The transistor 100T may be located in an active region partitioned by the bit line 120T and the word line 220 on the semiconductor substrate 210, and may be repeatedly arranged along rows and/or columns on the semiconductor substrate 210 to form a transistor array. The transistor 100T may be a vertical channel array transistor (VCAT) in which the transistor channel 110T extends perpendicular to the in-plane direction (e.g., any direction parallel to the xy plane) of the semiconductor substrate 210

Each transistor 100T may be electrically connected to the bit line 120T, the word line 220, and the capacitor 230 to play a switching role.

Referring to FIG. 13, a transistor 100T according to an example includes a transistor channel 110T, a gate electrode 224, a gate dielectric layer 240, a source electrode 273, and a drain electrode 275. The transistor 100T may be embedded in the dielectric layer 140.

The transistor channel 110T may extend perpendicular to the in-plane direction (e.g., any direction parallel to the xy plane) of the semiconductor substrate 210 on the semiconductor substrate 210. In this way, the transistor channel 110T is formed perpendicular to the in-plane direction (for example, any direction parallel to the xy plane) of the semiconductor substrate 210, so that, compared to a structure in which the transistor channel 110T is formed horizontally on the semiconductor substrate 210 or a structure embedded in the semiconductor substrate 210, an area of each unit cell may be effectively reduced and thus more unit cells may be formed on the semiconductor substrate 210. Therefore, a high integration integrated circuit device 1000 may be implemented.

The gate electrode 224 may be electrically connected to the word line 220 and may extend perpendicular to the in-plane direction (e.g., any direction parallel to the xy plane) of the semiconductor substrate 210. The gate electrode 224 and the transistor channel 100T may face each other with the gate dielectric 240 interposed therebetween. The gate electrode 224 may be formed of one or two or more layers.

The gate dielectric 240 may be disposed between the gate electrode 224 and the transistor channel 100T and may include a dielectric material. The gate dielectric 240 may include, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped metal oxynitride, or a combination thereof. The gate dielectric 240 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto.

The source electrode 273 and the drain electrode 275 may be disposed at the top and bottom of the transistor channel 100T. The source electrode 273 may be electrically connected to the capacitor 230 and the drain electrode 275 may be electrically connected to the bit line 120T. The drain electrode 275 may be a portion of the bit line 120T.

The capacitor 230 is electrically connected to the source electrode 273 of the transistor 100T and may include electrodes (not shown) facing each other and a dielectric layer (not shown) disposed therebetween. The capacitor 230 may have a cylindrical shape extending perpendicularly to an in-plane direction (e.g., any direction parallel to the xy plane) of the semiconductor substrate 210 but is not limited thereto.

An example of a DRAM device, which is an integrated circuit device, has been described above, but is not limited thereto and may be applied to all integrated circuit devices including conductive wire. For example, integrated circuit components may be used for arithmetic operations, program execution, and/or temporary data retention.

The aforementioned interconnect structure 100 and/or integrated circuit device 1000 may be included in various electronic devices. The electronic devices may include mobile devices, computers, laptops, tablet PCs, smart watches, sensors, digital cameras, e-books, network devices, vehicle navigation systems, Internet of Things (IoT) devices, Internet of Everything (IoE) devices, drones, door locks, safes, automated teller machines (ATMs), security devices, medical devices, or automotive electrical components, but are not limited thereto.

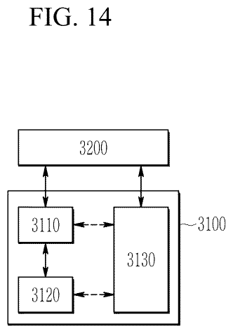

FIG. 14 is a conceptual view showing an example of an electronic device according to an embodiment.

Referring to FIG. 14, an electronic device 3100 according to an embodiment may include a memory unit 3110, an arithmetic logic unit 3120, and a control unit 3130, which may be electrically connected. For example, the memory unit 3110, the arithmetic logic unit 3120, and the control unit 3130 may be implemented as a single integrated circuit device (semiconductor chip), and may be monolithically integrated on a single substrate to be implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A method of manufacturing an interconnect structure, the method comprising:
forming a first dielectric layer defining therein a first trench,
embedding a first conductive layer in the first trench,
forming a second dielectric layer on the first dielectric layer and the first conductive layer,
forming a second trench in the second dielectric layer to expose at least a portion of an upper surface of the first conductive layer,
forming a carbon layer comprising a two-dimensional carbon material on the second dielectric layer and the at least a portion of the upper surface of the first conductive layer exposed through the second trench to expose a sidewall of the second dielectric layer in the second trench,
forming a first auxiliary layer on the sidewall of the second dielectric layer in the second trench using the carbon layer as a mask,
removing the carbon layer to expose the first conductive layer, and
embedding a second conductive layer in the second trench to contact the first conductive layer.

2. The method of claim 1, wherein the two-dimensional carbon material comprises intrinsic graphene, nanocrystalline graphene with a plurality of crystal grains, or a combination thereof.

3. The method of claim 1, wherein the forming of the carbon layer comprises supplying the two-dimensional carbon material in a direction parallel to the sidewall of the second dielectric layer in the second trench to deposit the carbon layer on the second dielectric layer and the at least a portion of the upper surface of the first conductive layer exposed through the second trench.

4. The method of claim 1, wherein the forming of the carbon layer comprises depositing the two-dimensional carbon material by chemical vapor deposition or atomic layer deposition.

5. The method of claim 1, further comprising forming a second auxiliary layer on a sidewall of the first dielectric layer in the first trench, prior to the embedding of the first conductive layer in the first trench.

6. The method of claim 5, wherein the forming of the first auxiliary layer and the forming of the second auxiliary layer comprise depositing a metal, a semi-metal, a metal oxide, a semi-metal oxide, a metal nitride, a semi-metal nitride, a metal carbide, a semi-metal carbide, or a combination thereof by atomic layer deposition.

7. The method of claim 1, further comprising surface-treating the carbon layer after the forming of the carbon layer,
wherein the surface-treating of the carbon layer comprises supplying a halogen atom, a nitrogen atom, an oxygen atom, a phosphorus atom, or a combination thereof to the carbon layer.

8. The method of claim 1, further comprising forming a third conductive layer electrically connected to the second conductive layer after the forming of the second conductive layer,
wherein the first conductive layer and the third conductive layer are each a wire, and
the second conductive layer is a via connecting the first conductive layer and the third conductive layer.

9. An interconnect structure, comprising:
a first dielectric layer and a second dielectric layer, which are sequentially stacked,
a first conductive layer embedded in the first dielectric layer,
a second conductive layer embedded in a trench of the second dielectric layer, the second conductive layer being in contact with an upper surface of the first conductive layer,
a first auxiliary layer between a side of the second conductive layer and an inner side of the second dielectric layer, and
a two-dimensional carbon material in contact with the side of the second conductive layer and an bottom surface of the first auxiliary layer.

10. The interconnect structure of claim 9, wherein an amount of the two-dimensional carbon material is about 0.001 atomic percentages (at%) to about 5 at % with respect to a total number of atoms within a same height as the two-dimensional carbon material in the trench of the second dielectric layer.

11. The interconnect structure of claim 9, wherein the two-dimensional carbon material comprises intrinsic graphene, nanocrystalline graphene with a plurality of crystal grains, or a combination thereof.

12. The interconnect structure of claim 9, further comprising a third conductive layer electrically connected to the second conductive layer,
wherein the first conductive layer and the third conductive layer are each a wire, and
the second conductive layer is a via connecting the first conductive layer and the third conductive layer.

13. The interconnect structure of claim 9, further comprising
a second auxiliary layer between the first conductive layer and the first dielectric layer, and
a carbon layer between the first auxiliary layer and the second auxiliary layer, the carbon layer comprising the two-dimensional carbon material.

14. The interconnect structure of claim 13, wherein
the first auxiliary layer and the second auxiliary layer each independently comprise a diffusion barrier layer, an adhesion auxiliary layer, or a combination thereof, and
the first auxiliary layer and the second auxiliary layer each independently comprise a metal, a semi-metal, a metal oxide, a semi-metal oxide, a metal nitride, a semi-metal nitride, a metal carbide, a semi-metal carbide, or a combination thereof.

15. An interconnect structure, comprising:
a first dielectric layer and a second dielectric layer, which are sequentially stacked,
a first conductive layer embedded in the first dielectric layer,
a second conductive layer embedded in the second dielectric layer, the second conductive layer being in contact with an upper surface of the first conductive layer,
a first auxiliary layer between a side of the second conductive layer and an inner side of the second dielectric layer,
a second auxiliary layer between the first conductive layer and the first dielectric layer, and
a carbon layer between the first auxiliary layer and the second auxiliary layer, the carbon layer comprising a two-dimensional carbon material.

16. The interconnect structure of claim 15, wherein the two-dimensional carbon material comprises intrinsic graphene, nanocrystalline graphene with a plurality of crystal grains, or a combination thereof.

17. The interconnect structure of claim 15, further comprising a third conductive layer electrically connected to the second conductive layer,
wherein the first conductive layer and the third conductive layer are each a wire, and
the second conductive layer is a via connecting the first conductive layer and the third conductive layer.

18. The interconnect structure of claim 15, wherein
the first auxiliary layer and the second auxiliary layer each independently comprise a diffusion barrier layer, an adhesion auxiliary layer, or a combination thereof, and
the first auxiliary layer and the second auxiliary layer each independently comprise a metal, a semi-metal, a metal oxide, a semi-metal oxide, a metal nitride, a semi-metal nitride, a metal carbide, a semi-metal carbide, or a combination thereof.

19. An integrated circuit device comprising the interconnect structure of claim 9.

20. An integrated circuit device comprising the interconnect structure of claim 15.
